(19) United States
(12) Patent Application Publication
(10) Pub. No.: US 2010/0045311 A1
(43) Pub. Date: Feb. 25, 2010

(54) Dual Electrical Current Sourcing-piezoresistive Material Self-Sensing (DEC-PMSS) System

(76) Inventor: Jaycee Howard Chung, Heath, TX (US)

Correspondence Address: WILSON DANIEL SWAYZE, JR., 3804 CLEARWATER CT., PLANO, TX, 75025, US

(21) Appl. No.: 12/195,140

(22) Filed: Aug. 20, 2008

(51) Int. Cl. G01R 27/08

(52) U.S. Cl. 324/718

(57) ABSTRACT

In the two-probe case, a detector circuit to detect stress or damage in an object may include a first electrode to be positioned on the object, a second electrode to be positioned on the object, a current circuit to measure the current to the first electrode, a voltage circuit to generate a voltage for the first electrode, a controller circuit to determine and record the changing impedance between the first electrode and a second electrode. In the four-probe case, a detector circuit to detect stress or damage in an object may include a first electrode to be positioned on the object, a second electrode to be positioned on the object, a third electrode to be positioned on the object, a fourth electrode to be positioned on the object, a current source to generate current to the first electrode, a current circuit to measure the current to the second electrode, a voltage circuit to measure the voltage between the third and fourth electrodes, a controller circuit to determine and record the changing impedance between the third electrode and the fourth electrode.

### FIELD OF THE INVENTION

The present invention relates to detector circuits and more particularly to a detector circuit which may detect damage and stress to a material.

### BACKGROUND OF THE INVENTION

When a structural material contains carbon fibers, the material may become semi-conductive and piezoresistive. Piezoresistivity provides a way of assessing the damage resulting from strain on a structure made of a piezoresistive material. Carbon fibers may be widely used for the construction of composite structures due to low cost and high performance characteristics. When fractional carbon fibers are mixed in a cement or concrete material, the construction material may become piezoresistive. It can be designated as “smart cement” or “smart concrete”.

### REFERENCE

1. Jaycee H. Chung, Graphite-Epoxy Composite Parts Electrical Conductivity Tests for Damage Detection, E-Systems 1993 Structures Technologies IR&D Technical Report, 1993.
2. Jaycee H. Chung, Embedded Sensing Capability for Composite Structures, Global Contour Ltd. US Army SBIR Phase I, Report No. USAAMCOM TR-03-D-26, 15 Jun. 2003.
3. Jaycee H. Chung, Composite Structural Self-Diagnosis via. Electrical Resistance, AFOSR STTR Phase I, Report No. GC/AFOSR-CS-STTR-I, June 2004.
4. Jaycee H. Chung, Composite Structural Damage Self-Sensing via Electrical Resistance Measurement, Global Contour Ltd. NSF SBIR Phase I, Report No. DMI-0315851, January 2004.
5. Jaycee H. Chung, Composite Structural Damage Self-Sensing Technology, Global Contour Ltd. NSF SBIR Phase II Interim Report, Grant DMII-0422146, January 2005.
6. Jaycee H. Chung, Multifunctional Material Properties-based Smart Concrete Structural Self-Sensing (MMP-SCSS) Technology, Army 05-124 SBIR Phase I Final Report, W912HZ-06-P-0016, May 2006.
7. “LabVIEW 7 Express”, R. Bishop, Prentice Hall, NJ, ISBN 0-13-188054-3.

### SUMMARY

A detector circuit to detect stress or damage in an object may include a first electrode to be positioned on the object, a second electrode to be positioned on the object, a current circuit to measure the current to the first electrode, a voltage circuit to generate a voltage for the first electrode, a controller circuit to determine and record the changing impedance between the first electrode and a second electrode.

The voltage circuit may be a DC circuit, and the voltage circuit may be an AC circuit.

The current circuit may be an ammeter, and the controller circuit may determine damage or strain of the object by comparing successive resistance values of the object.

The controller circuit may determine damage or strain of the object by comparing successive the impedance values of the object to those of the undamaged state of the object.

A detector circuit to detect stress or damage in an object may include a first electrode to be positioned on the object, a second electrode to be positioned on the object, a third electrode to be positioned on the object, a fourth electrode to be positioned on the object in a linear fashion (four-probe method), a current is applied through the outer electrodes, the first and the fourth electrodes, to generate a current field between the electrodes. The voltage is measured through the inner electrodes, the second and the third electrodes, and a controller circuit to determine and record the changing impedance between the third electrode and the fourth electrode.

The current source and the current circuit may be connected together, and the controller circuit may determine damage or strain of the object by comparing successive resistance values to resistance value of the original undamaged state of the object.

The controller may include an analog MUX, and a controller may include a signal amplifier. The controller may include a serial port, and the serial port may be connected to a computer.

### BRIEF DESCRIPTION

The invention may be understood by reference to the following description taken in conjunction with the accompanying drawings, in which:

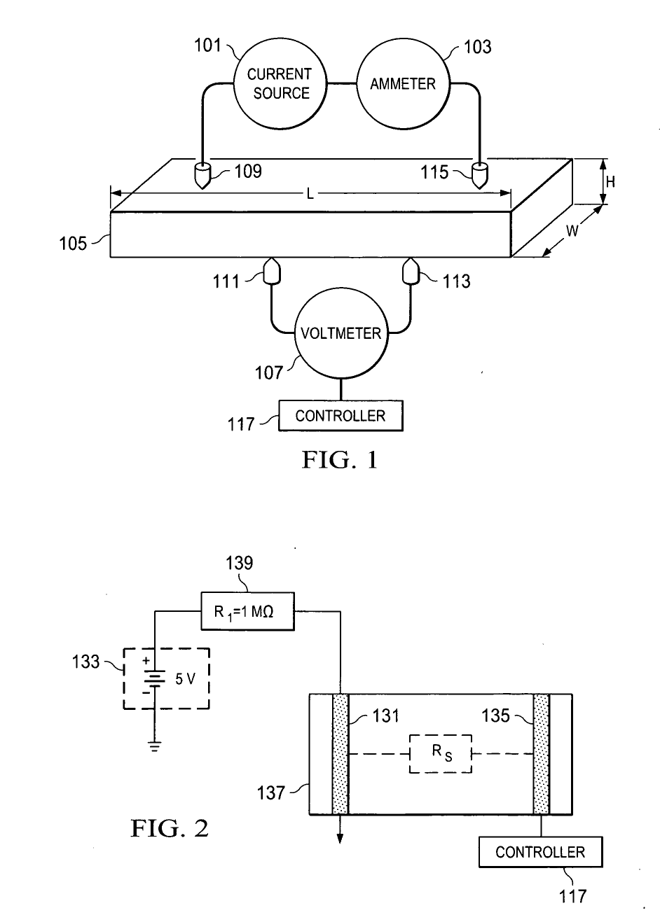

FIG. 1 illustrates a circuit diagram of a four probe system in accordance with the teachings of the present invention;

FIG. 2 illustrates a circuit diagram of a two probe system in accordance with the teachings of the present invention;

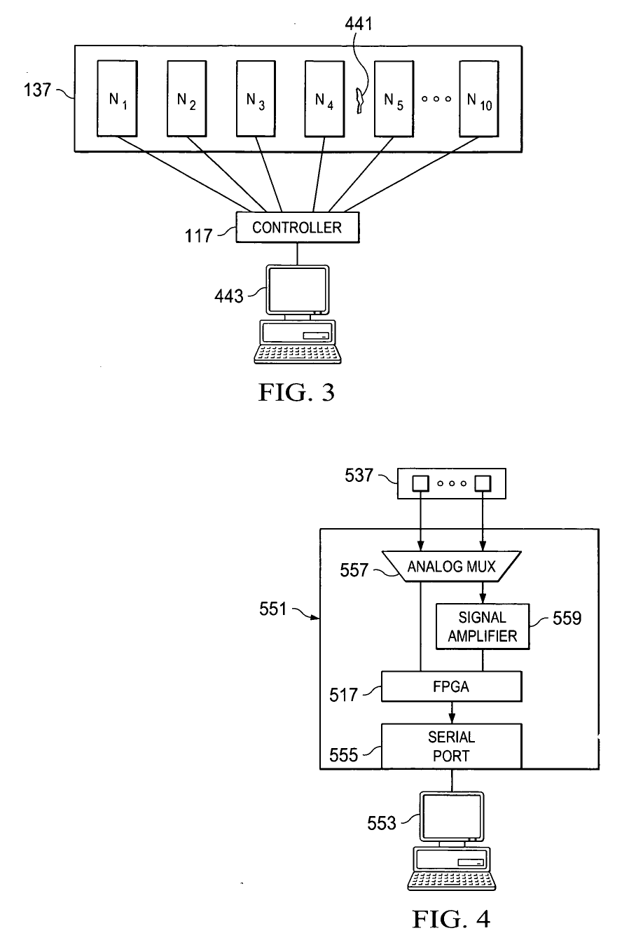

FIG. 3 illustrates a circuit diagram of a multi-probe system in accordance with the teachings of the present invention;

FIG. 4 illustrates a circuit diagram of an analysis system in accordance with the teachings of the present invention.

### DETAILED DESCRIPTION

From extensive research and development [1-6], a piezoresistivity-based self-sensing system/technique was developed. The system/technique can be used to determine the damage to the material and strain/stress on the material. The system/technique is named Dual Electrical Current sourcing Piezoresistive Material Self-Sensing (DEC-PMSS), and DEC-PMSS includes a stand-alone Nodal Electrical Resistance Acquisition Circuit (NERAC) hardware device and Piezoresistivity Analyzer (PA) software residing in a data-processing personal computer (PC). Therefore, the NERAC and PA are included in the DEC-PMSS system/technique architecture.

DEC-PMSS may be used to perform structural health monitoring (SHM) of the material. Strain/stress assessment based on multifunctional material properties may be made through measuring electrical resistance changes in a piezoresistive material structure, e.g., carbon fiber composite structure, fractional micro-carbon fiber, short carbon nanotube or carbon nano fiber-mixed engineered construction material (a.k.a., smart cement and/or smart concrete) structure. Such strain/stress and/or damage sensing may be referred to as “self-sensing” as the structural material itself may work as a sensor without involving additional embedded or attached sensors.

The electrical resistivity may be acquired via either a two-probe technique or a four-probe technique. The two-probe method may measure electrical voltage from two electrical contacts (electrodes) while sourcing AC or DC current. On the other hand, the four-probe method may measure electrical voltage between two inner electrodes while running electrical current through two outer electrodes. Thus, the two-probe method may measure direct resistivity, and the four-probe method may measure electric potential. Both techniques possess advantages and disadvantages. Either method for electrical resistance acquisition may be used for self-sensing of the piezoresistive materials for structural health monitoring and strain/stress assessment which may be utilized for diversified applications.

Results from research conducted [1-6] have shown that electrical resistance may potentially yield information about damage inflicted on a composite material. In addition to demonstrating proof of concept for a compact, easy to use nodal resistance measurement system controlled by a computer, the research showed that there was a significant difference (statistical confidence level of substantially 95%) between resistance measurements from the composite substrate, before and after the infliction of damage to the material. Recently, a pre-prototype version (research version prototype) of the NERAC system was designed fabricated and tested using a Field Programmable Gated Array (FPGA) chip as the main controller and LabVIEW® as the Graphical User Interface (GUI). Results from this study corroborated previous research and vindicated conclusions from feasibility studies.

Different methods have been proposed for measuring the resistance of multi-functional materials. The methods may be performed via either AC or DC sourcing. In DC resistance measurement, a constant voltage potential is applied to generate an electrical current field in a piezoresistive material specimen. A method for acquiring resistance is the four-point collinear method. The two-probe method can be used for direct resistance measurement, however, the two-probe measurement can be affected by contact resistivity of interfacing material (electrode). The following may describe the basic resistance measurement methods. Damage may be defined as irreversible (unrecoverable) change in resistance that may have resulted from some force being applied to the material. Strain/stress may be measured based reversible (recoverable) change in resistance when loading condition is removed.

(i) The Four-Point Collinear Probe

Method Application One way of measuring the resistivity of a semiconductor material may be by using a four-point collinear probe. A diagram a detector circuit of the four-point probes technique is shown in FIG. 1. This technique involves bringing four substantially equally spaced probes for example first electrode 109, second electrode 111, third electrode 113 and four electrode 115 in contact with a material or object 105 which may include piezoresistive material of unknown resistance. The two outer probes, the first electrode 109 and the fourth electrode 105 are used for sourcing current which may be generated by current source 101, and the two inner probes for example the second electrode 111 and the third electrode 113 may be used by the voltmeter 107 for measuring the resulting voltage drop between the two inner probes for example the second electrode 111 and the third electrode 113. A history of voltage drops may be determined and the changing nature of the voltage drop or resistance may indicate stress/strain or damage to the material when resistance change is analyzed with PA.

(ii) Two-Point Probe Technique

The resistivity of a material such as object 137 may also be obtained by measuring the resistance and physical dimensions of a bar of material, as shown in FIG. 2. FIG. 2 illustrates a detector circuit of a two point probe technique. In this example, the material is in the shape of a rectangular bar of length l, height h, and width w. Other shapes are within the scope of the present invention. Copper wires or other suitable wires are attached to both ends of the bar by electrode 113, 135. This is called the two-point probes technique, since wires are attached to the material at two points. A voltage source 113 applies a voltage V across the bar and through the wires and electrodes 131, 135, causing a current I to flow through the bar. (Alternatively, a current source could force current through the sample bar, while a voltmeter in parallel with the current source measures the voltage induced across the sample bar.) The amount of current I that flows through the bar 137 is measured by the ammeter 139, which is connected in series with the bar 137 and voltage source 133. The voltage drop across the ammeter 139 may be negligible. Ohm's law gives the resistance R of the bar. Depending upon the interface conductivity, contact resistance may affect the result in the two-probe measurement. The resistance values are stored and analyzed by the controller 117 to determine a strain or damage.

(iii) AC Application to Minimize Polarization Effect

For the above resistance measurement, AC or DC power source can be used as described below. However, when DC is repeatedly applied to hydrophilic materials, e.g., smart cement or smart concrete, polarization may occur. The polarization may cause inaccurate results in voltage measurement, and thus, provides unreliable resistance values.

Unlike DC sourcing, the AC application may cause little or no polarization effect, and thus, may result in strain measurements with greater accuracy. A low frequency AC current (substantially high frequency) can be provided by an external circuit or function generator to bias object 105 (four-probe case), 137 (two-probe case), or specimens with the voltage potential varying substantially from −5V to 5V with other voltages being within the scope of the present invention.

Under the AC bias, the impedance Z (a complex quantity) includes the resistance Rₛ (real part of Z) and the reactance Xₛ (imaginary part of Z), i.e., Z=Rₛ+jXₛ, where the subscript s may refer to a configuration in which the sample is in series connection with the measuring circuit. AC bias provides both resistance and reactance information adding another dimension to the results, and AC bias may be also relevant to data acquisition by wireless methods. It has been found that in fractional micro carbon fiber reinforced (cement) mortar at substantially 28 days of curing or other appropriate time periods, the reactance Xs may be a more sensitive indicator than the resistance Rs, as the fractional change in reactance may exceed the fractional change in resistance upon deformation. The effect of strain on the reactance relates to the effect of strain on the polarization, i.e., the direct piezoelectric effect, which is different from the piezoresistive effect.

Both strain and damage can be sensed simultaneously through electrical resistance measurement and analysis performed by the controller 117. Thus, the strain/stress condition (during dynamic loading) under which damage occurs can be obtained, facilitating damage origin identification. Damage is indicated by a resistance increase, which is larger and less reversible when the stress amplitude is higher. The instantaneous resistance change can be a gradual or sudden depending upon the type of a load applied.

(iv) Applications

The invention includes a self-sensing method, relevant electronic hardware and post-processing software. The present invention may achieve damage detection/progression monitoring and strain/stress assessment on carbon fiber composite structure and other piezoresistive materials such as smart cement and smart concrete. The self-sensing system/technique was developed based on the multifunctional characteristics of the piezoresistive structural materials for diversified applications, e.g., structural health monitoring (SHM), cargo-truck weighing in motion, border traffic monitoring, intrusion detection for security monitoring, etc. This invention builds on the research and development performed under several different projects as listed below [1-6], and the technology improvements may be in progress under National Science Foundation Small Business Innovative Research (SBIR) grant on carbon fiber composite self-sensing, and the U.S. Army Corps of Engineer's (CoE) SBIR project on smart construction material self-sensing.

A schematic representation of DEC-PMSS system/technique and detector circuit may be illustrated in FIG. 3. One-dimensional linear electrodes may be used to describe both two-probe and four-probe techniques. Linear (in line formation of the electrodes) surface or sub-surface embedded electrical contacts (electrodes) may be used. A multi-dimensional placement of the electrodes is within the scope of the invention. The electrodes are designated as N_{1,} N_{2,} N_{3 . . .} and N₁₀ in FIG. 3.

Four (4) electrodes among N_{1,} N_{2,} N_{3 . . .} and N₁₀ used for data acquisition in the four-probe application case, while only two (2) electrodes are used in the two-probe application case. In the four-probe application, electrical current is supplied via two outer electrodes which form an electrical field between them, and electrical resistance (potential) is measured with the remaining two (2) inner electrodes. For example, to form an electrical field, AC or DC electric current is supplied though N₁ and N₁₀ electrodes. In that case, a broad electrical field is formed an area between N₁ and N₁₀. Using any two of the remaining electrodes among N_{2,} N_{3 . . .} and N₉, electric potential is measured in an area between the two selected inner electrodes. For example, when damage 441 is inflicted between N₄ and N₅ as shown above, electrical resistance increases between N₄ and N₅ electrodes. Comparing the measured electrical resistivity values to the initial undamaged condition (baseline) resistivity value acquired by the controller 117, it may be determined whether or not damage may have been inflicted in an area of interest through PA-installed 413 computer.

On the other hand, in the two-probe application case, only two (2) electrodes are used for voltage measurement. For example, electrical voltage is measured through the current sourcing nodes, N₄ and N₅ electrodes while AC or DC current is supplied via the same electrodes. This may be a more direct method of self-sensing by running AC or DC electrical current through two electrodes. This method may be easier to apply than the four-probe method, especially in particular circumstances. In practice, a fatigue damage-prone structure may not provide sufficient room for four-electrode installation resulting from a tight corner, narrow edge distance, and short rivet hole distance. In such cases, the two-probe method may be preferred over the four probe method. However, the two-probe measurement is easily affected by contact resistivity resulting in inaccurate resistivity result. The two-probe method may be effective if contact resistivity is eliminated.

No matter which technique is used, an automated data acquisition micro-controller built-in 117 may be included to perform sequential and systematic electrical conductivity/resistivity acquisition. The microprocessor or controller 117 built-in NERAC is the data acquisition device of this DEC-PMSS system architecture, which is capable of measuring electrical resistivity of a piezoresistive material structure systematically in a sequential manner over time, performing local data-retrieving and local-processing captured data.

The above technique may be applied to SHM and strain/stress assessment on carbon fiber composites used in various fields, e.g., manned and unmanned aircraft/rotorcraft flight critical composite structural components, composite bridge structures, off-shore petroleum production composite risers, smart cement/concrete (e.g., bridges, dams, building structures, highway interchange support structures, tunnels, etc.) The controller of 117 may be in wireless communication with system computer, 443.

Strain/stress assessment may be performed in a similar fashion to the above damage detection. The difference between the two methods is that the damage detection may be based on irreversible (unrecoverable) resistivity (due to permanent deformation) analysis, and strain assessment may be based on reversible (recoverable) resistivity (elastic deformation) analysis. In strain analysis, actual localized deflections may be determined by applying various levels of load. It can be performed analytically (e.g., finite element analysis) or experimentally. Then, strain/stress levels may be correlated to the recoverable resistivity levels prior to in-service strain/stress assessment. This allows various types of monitoring that may be accomplished for example: (1) automobile weighing in motion on a smart concrete pavement-highway, (2) border traffic monitoring, (3) intrusion detection on a smart concrete facility, etc. The above DEC-PMSS system/technique may be applied to the structures made of most types of piezoresistive materials.

### Analytical Tools

The above description may use linear electrodes for the ease of explanation of one-dimensional self-sensing technique. The teachings of the present invention may apply to various dimensions and various types of electrical contacts (electrodes) can be used for data acquisition, e.g., line, circular, dot (point), subsurface embedded mesh, etc. After obtaining a series or sequence in time of resistance data or impedance data obtained from an object specimen (structure) using one of the above method, this technique may utilize a commercially available finite element analysis (FEA) code along with other commercial software, e.g., LabVIEW® [7] for post-processing to translate the series or sequence of time of the resistance data or impedance data to reversible strain or permanent damage identification. In order to utilize the commercial software, interfacing/translating software (a series of programs) was developed. Thus, the proclaimed invention includes the above hardware (DEC-NERAC) and interfacing/translating software (PA) with the exception of the above commercially available software.

### DEC-NERAC System Design

As shown in FIG. 4, the resistance/resistivity of an object 537 may be measured using at least two electrodes in either of the above techniques. The electrodes may be connected to the NERAC circuit, 551 that will process the analog information, quantify and convert it to digital data to be displayed as a read-out on the user interface software-housed monitoring laptop 553 or PC. The NERAC circuit 551 may serve as the interface circuitry, which can be added to a laptop or PC as a PC card, or an interfacing data acquisition board. The NERAC circuit 551 may communicate with a monitoring computer 553 using a serial port 555 of the NERAC circuit 551. The NERAC circuit 551 may include the following components, as shown in FIGS. 4.
Analog multiplexers 557 (MUX) to provide for expansion to multiple probes so that multiple areas can be simultaneously evaluated.
Analog signal conditioning module 559 to provide for substantially signal noise elimination, truncation, etc.
Analog to Digital Converter (A/D) (not shown) for data quantification and digital coding of the analog signal to a digital form.
FPGA Controller 517 for the circuit to store the series or sequence in time resistance or impedance values and to evaluate the series or sequence in time resistance or impedance values in order to determine the presence and extent of strain or damage to the object under consideration.
Serial port 555 for communication with LabVIEW® software which may be hardwired or wireless.
Monitoring computer 553 with LabVIEW® and interfacing software installed.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed.

1. A detector circuit to detect stress or damage in an object, comprising:
a first electrode to be positioned on the object;
a second electrode to be positioned on the object;
a current circuit to measure the current to the first electrode;
a voltage circuit to generate a voltage for the first electrode;
a controller circuit to determine and record the changing impedance between the first electrode and a second electrode.

2. A detector circuit to detect stress or damage in an object as in claim 1, wherein the voltage circuit is a DC circuit.

3. A detector circuit to detect stress or damage in an object as in claim 1, wherein the voltage circuit is an AC circuit.

4. A detector circuit to detect stress or damage in an object as in claim 1, wherein the current circuit is an ammeter.

5. A detector circuit to detect stress or damage in an object as in claim 1, wherein the controller circuit determines damage or strain of the object by comparing successive resistance values of the object.

6. A detector circuit to detect stress or damage in an object as in claim 3, wherein the controller circuit and computer determine damage or strain of the object by comparing successive the impedance values of the object.

7. A detector circuit and computer to detect stress or damage in an object as in claim 6, wherein the controller circuit determines damage or strain of the object by comparing the imaginary value of the impedance of the object.

8. A detector circuit to detect resistivity to identify stress or damage in an object, comprising:
a first electrode to be positioned on the object (outer electrode);
a second electrode to be positioned on the object;
a third electrode to be positioned on the object;
a fourth electrode to be positioned on the object;
a current source to generate current to the first electrode;
a current circuit to measure the current to the second electrode;
a voltage circuit to measure the voltage between the third and fourth electrodes;
a controller circuit to determine and record the changing impedance between the third electrode and the fourth electrode.

9. A detector circuit to detect resistivity to determine stress/strain or damage in an object as in claim 8, wherein the current source and the current circuit are connected together.

10. A detector circuit to detect resistivity to determine stress/strain or damage in an object as in claim 8 wherein the controller circuit determine resistivity value change for damage or strain detection on the object by comparing successive resistance values of the object.

11. A detector circuit to detect resistivity to determine stress/strain or damage in an object as in claim 8, wherein the controller includes an analog MUX.

12. A detector circuit to detect resistivity to determine stress/strain or damage in an object as in claim 8, wherein a controller includes a signal amplifier.

13. A detector circuit to detect resistivity to determine stress/strain or damage in an object as in claim 8, wherein the controller includes a serial port.

14. A detector circuit to detect resistivity to determine stress/strain or damage in an object as in claim 13, wherein the serial port is connected to a computer.
